(19) United States
(12) Patent Application Publication
(10) Pub. No.: US 2009/0191713 A1
(43) Pub. Date: Jul. 30, 2009

(54) METHOD OF FORMING FINE PATTERN USING BLOCK COPOLYMER

(75) Inventors: Dong-Ki YOON, Seoul (KR); Hyun-Woo KIM, Gyeonggi-do (KR); Shi-Yong YI, Gyeonggi-do (KR); Hai-Sub NA, Gyeonggi-do (KR); Kyoung-Taek KIM, Incheon (KR); Yun-Kyeong JANG, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/235,361

(22) Filed: Sep. 22, 2008

(30) Foreign Application Priority Data
Jan. 29, 2008 (KR) 2008-0009059

(51) Int. Cl. H01L 21/311

(52) U.S. Cl. 438/703; 257/E21.249

(57) ABSTRACT

Provided is a method of forming a fine pattern using a block copolymer. The method comprises forming a coating layer including a block copolymer having a plurality of repeating units on a substrate. A mold is provided having a first pattern comprising a plurality of ridges and valleys. The first pattern is transferred from the mold into the coating layer. Then, a self-assembly structure is formed comprising a plurality of polymer blocks aligned in a direction guided by the ridges and valleys of the mold thereby rearranging the repeating units of the block copolymer within the coating layer by phase separation while the coating layer is located within the valleys of the mold. A portion of the polymer blocks are removed from among the plurality of polymer blocks and a self-assembly fine pattern of remaining polymer blocks is formed.

### CROSS-REFERENCE TO RELATED PATENT APPLICATION

This application claims the benefit of Korean Patent Application No. 10-2008-0009059, filed on Jan. 29, 2008, in the Korean Intellectual Property Office, the disclosure of which is incorporated herein in its entirety by reference.

### BACKGROUND

1. Field of the Technology

The present technology relates to a method of forming a fine pattern for manufacturing a semiconductor device, and more particularly, to a method of forming a fine pattern using a block copolymer.

2. Description of the Related Art

As the integration of semiconductor devices has increased, a plane area occupied by each unit cell has decreased. In response to such a decrease in the plane area, a design rule of a nano-scale critical dimension (CD) that is smaller than several to several tens of nanometers is applied. Accordingly, a new technology for forming a fine pattern, such as a fine contact hole pattern having a nano-scale opening size or a fine line pattern having a nano-scale width, is required.

When only a photolithography technology using a top-down method is used in order to form a fine pattern for manufacturing a semiconductor device, there may be a limit to improving the resolution due to the wavelength of a light source and the resolution limit of an optical system.

In order to overcome the limit to improving the resolution in the photolithography technology and in order to develop the next generation of micro-machining technology, methods of forming a fine structure in a bottom-up method using a self-assembly phenomenon of molecules are used. However, a conventional method of forming a fine pattern using self-assembly of molecules is still in an experimental stage, and thus is difficult to apply when trying to realize a fine pattern for actually manufacturing a semiconductor device. Accordingly, the forming of a fine pattern in a nano-scale required in a highly integrated semiconductor device requires a method of forming a fine pattern that can be readily applied to a device manufacturing process and can form a repetitive structure having a large area for mass production.

### SUMMARY

The present technology provides a method of forming a fine pattern of a semiconductor device, which can readily realize a pattern having a fine pitch which is required in manufacturing a highly integrated semiconductor device that overcomes a resolution limit in a photolithography process.

According to an aspect of the present technology, a method of forming a fine pattern on a semiconductor device is provided. The method comprises forming a coating layer including a block copolymer having a plurality of repeating units on a substrate. A mold is provided having a first pattern comprising a plurality of ridges and valleys. The first pattern is transferred from the mold into the coating layer. Then, a self-assembly structure is formed comprising a plurality of polymer blocks aligned in a direction guided by the ridges and valleys of the mold thereby rearranging the repeating units of the block copolymer within the coating layer by phase separation while the coating layer is located within the valleys of the mold. A portion of the polymer blocks are removed from among the plurality of polymer blocks and a self-assembly fine pattern of remaining polymer blocks is formed.

In one embodiment, the method further includes forming of the coating layer comprising spin-coating a mixture including the block copolymer and an organic solvent on the substrate. In another embodiment, the mixture further includes an acid and a surfactant. In still another embodiment, the block copolymer and the acid are mixed in a molar ratio from about 1:1 to 1:1.5. In a further embodiment, the block copolymer and the surfactant are mixed in a molar ratio from about 1:1 to 1:1.5. In still a further embodiment, the block copolymer comprises polystyrene-co-poly(4-vinylpyridine) (PS-co-P4VP), the acid comprises methanesulfonic acid (MSA), and the surfactant comprises 3-n-pentadecylphenol (PDP).

In an embodiment herein, the block copolymer is formed of a multi-component block copolymer including a plurality of repeating units having different polymeric structures. In another embodiment, the block copolymer is a triblock copolymer in which a first repeating unit and a second repeating unit are covalently bonded as follows: (first repeating unit)-co-(second repeating unit)-co-(first repeating unit). In still another embodiment, the block copolymer is a triblock copolymer in which the first repeating unit, the second repeating unit, and a third repeating unit are covalently bonded as follows: (first repeating unit)-co-(second repeating unit)-co-(third repeating unit). In a further embodiment, the block copolymer is a diblock copolymer in which the first repeating unit and the second repeating unit are covalently bonded as follows: (first repeating unit)-co-(second repeating unit).

In one embodiment, the ridges and valleys of the mold each have substantially uniform widths. In another embodiment, at least a portion of the valleys have substantially larger widths than the ridges. In an embodiment, during the transferring of the first pattern, a self-assembled monomolecular (SAM) layer formed of an organic monomolecular layer is produced on the surfaces of the ridges and the valleys. In another embodiment, the SAM layer comprises any one of hexamethyldisilazane (HMDS), aminopropyltriethoxysilane, 4-mercaptopyridine, and aminoethanethiol.

In an embodiment herein, before transferring of the first pattern, a first area of the mold is surface processed so that the first area has greater affinity for a repeating unit of the block copolymer. In a further embodiment, the ridges include sidewalls, and the first area comprises the sidewalls of the ridges of the mold. In still a further embodiment, the surface processing of the first area is performed using one of a piranha solution process, a thermal process, or a UV-ozone process.

In one embodiment of the method herein, before the transferring of the first pattern, a second area is surface processed so that the second area does not have a selective affinity for the repeating units of the block copolymer. In a further embodiment, the valleys comprise bottom surfaces, and the second area comprises the bottom surfaces. In still further embodiments, the surface processing of the second area comprises forming a random block copolymer layer. Furthermore, the random block copolymer layer can include the same repeating units as the block copolymer in the coating layer.

In one embodiment, the mold is formed of one of silicon or polydimethylsiloxane (PDMS). In another embodiment, during the forming of the self-assembly structure, heat is applied to the coating layer so as to rearrange the repeating units of the block copolymer in the coating layer via phase separation. In still another embodiment, in the forming of the self-assembly structure, UV is irradiated onto the coating layer so as to rearrange the repeating units of the block copolymer in the coating layer via phase separation. In still another embodiment, the plurality of polymer blocks in the self-assembly structure are self-assembled as at least one of a sphere, cylinder, lamellar, gyroid, or hexagonal perforated cylinder (HPL) structure.

In an embodiment, the coating layer comprises the block copolymer, acid for combining with the block copolymer so that the block copolymer accepts a hydrogen bond, and a surfactant for providing hydrogen bonding to the block copolymer. In a further embodiment, the acid comprises methanesulfonic acid (MSA), and the surfactant comprises 3-n-pentadecylphenol (PDP).

In an embodiment herein, before removing said portion of the polymer blocks, the pitch is changed when the plurality of repeating units of the polymer blocks are rearranged. In another embodiment, before removing some of the polymer blocks, a tuned self-assembly structure is formed by increasing the widths of at least a portion of the polymer blocks. In still another embodiment, the polymer blocks include a surfactant, and a selective melting characteristic based on the temperature of the surfactant is used to form the tuned self-assembly structure. Moreover, in a further embodiment, the temperature of the self-assembly structure is adjusted above ambient temperature to form the tuned-self-assembly structure.

In one embodiment, in forming the self-assembly fine pattern, the plurality of polymer blocks are processed using one of an ozone, UV irradiation, or oxygen plasma process to remove at least a portion of the polymer blocks. In another embodiment, the self-assembly fine pattern comprises selectively hardening at least a portion of the remaining polymer blocks. In still another embodiment, selectively hardening at least a portion of the remaining polymer blocks comprises exposure to one of OSO₄ or RuO.

In an embodiment, before the forming of the coating layer, an image layer is formed on the substrate, wherein the coating layer is formed on the image layer. In a further embodiment, the image layer is formed of a random block copolymer. In still a further embodiment, the image layer is formed of a monomolecular layer self-assembled by a chemical bond on the surface of the substrate. In another embodiment, before the forming of the image layer, an etching layer is formed on the substrate, wherein the image layer is formed on the etching layer. In still another embodiment, the etching layer is formed of one of an oxide layer, a nitride layer, a nitride oxide layer, a doped polysilicon layer, or a metal layer. In an alternative embodiment, before forming the image layer, the top surface of the etching layer is surface processed so that Si—OH is exposed on the top surface of the etching layer. In an additional embodiment, the method further comprises exposing the etching layer by etching an exposed portion of the image layer, using the self-assembly fine pattern as an etch mask, and etching the etching layer using the self-assembly fine pattern as an etch mask.

### BRIEF DESCRIPTION OF THE DRAWINGS

The above and other features and advantages of the present technology will become more apparent by describing in detail exemplary embodiments thereof with reference to the attached drawings in which:

FIGS. 1A through 1K are diagrams for describing a method of forming a fine pattern according to an embodiment of the present technology;

FIGS. 2A and 2B are diagrams for describing a method of forming a fine pattern according to another embodiment of the present technology; and

FIGS. 3A and 3B are diagrams for describing a method of forming a fine pattern according to another embodiment of the present technology.

### DETAILED DESCRIPTION

The present technology will now be described more fully with reference to the accompanying drawings, in which exemplary embodiments of the technology are shown.

The technology may, however, be embodied in many different forms and should not be construed as being limited to the embodiments set forth herein; rather, these embodiments are provided so that this disclosure will be thorough and complete, and will fully convey the concept of the technology to those of ordinary skill in the art. Elements and regions in the drawings are briefly illustrated. Thus, the present technology shall not be limited by relative sizes or intervals illustrated in the drawings.

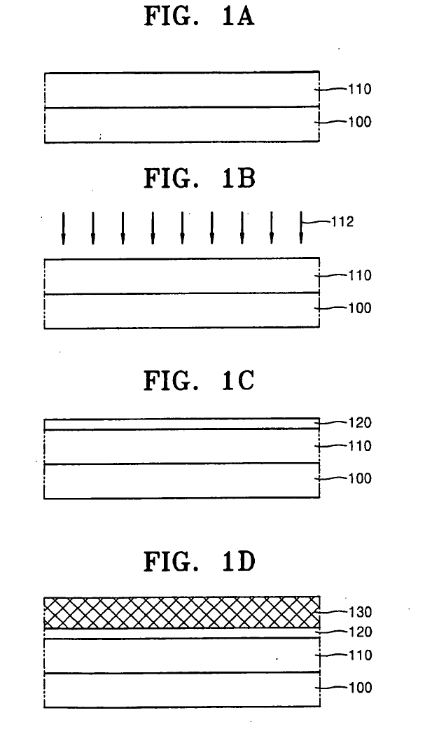

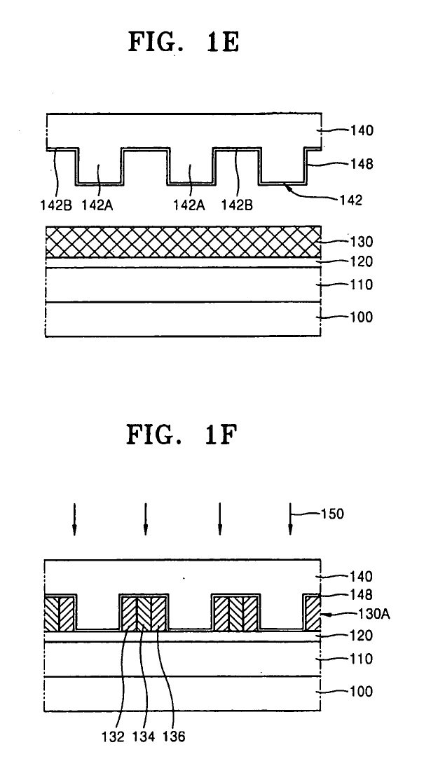

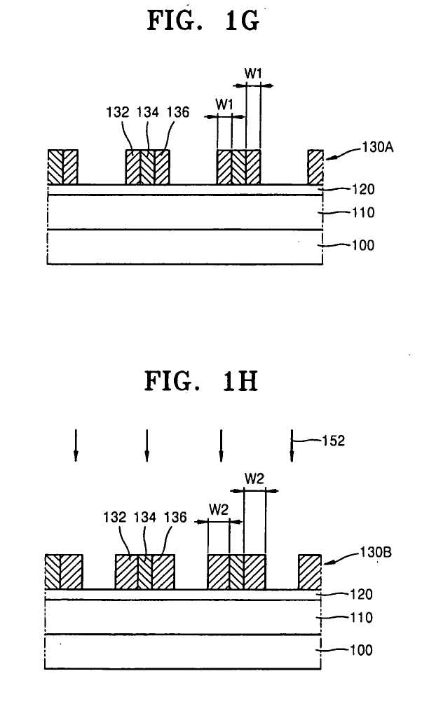

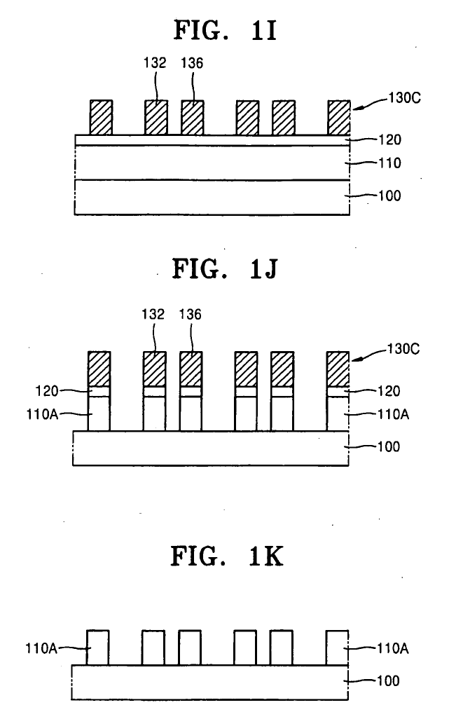

FIGS. 1A through 1K are diagrams for describing a method of forming a fine pattern 110A according to an embodiment of the present technology;

Referring to FIG. 1A, an etching layer 110 is formed on a substrate 100.

The substrate 100 may be a semiconductor substrate, such as silicon.

The etching layer 110 may in one embodiment be an insulation layer or a conductive layer. For example, the etching layer 110 may be an insulation layer, such as an oxide layer, a nitride layer, or a nitride oxide layer, or a conductive layer, such as a doped polysilicon layer or a metal layer. The etching layer 110 may be used as a hard mask for etching the substrate 100. When a fine pattern is to be formed by etching the substrate 100, the etching layer 110 may not be included.

Referring to FIG. 1B, the top surface of the etching layer 110 that is exposed on the substrate 100 is surface processed by using a chemical substance 112 so as to expose Si—OH on the surface of the etching layer 110.

In an embodiment herein, the chemical substance 112 may be a basic solution or an HF solution. For example, so as to surface process the exposed top surface of the etching layer 110, the etching layer 110 may be dipped in approximately 1 to 5 mM of tetraethylammonium hydroxide (TEAH) aqueous solution for approximately 1 to 60 minutes. Then, the surface processed etching layer 110 can be washed with distilled water and dried in a room temperature under a nitrogen atmosphere.

If the process of forming the etching layer 110 is not performed in FIGS. 1A and 1B, Si—OH can be exposed on the top surface of the substrate 100 so as to surface process the top surface of the substrate 100. If the etching layer 110 formed of a metal layer is formed on the substrate 100, the surface process using the chemical substance 112 may not be performed.

Referring to FIG. 1C, an image layer 120 can be formed on the etching layer 110.

The image layer 120 may be a random block copolymer. In one embodiment the block copolymer is formed of a diblock copolymer, and in another embodiment the block copolymer is a triblock copolymer. In a further embodiment the image layer 120 may be a random block copolymer formed of polymer blocks having the same structure as each unit polymer block forming a block copolymer coating layer that is to be formed on the image layer 120. For example, a block copolymer coating layer including polystyrene-co-poly(4-vinylpyridine) (PS-co-P4VP) is to be formed on the image layer 120. In an embodiment, the image layer 120 may be formed by spin coating a PS-r-P4VP polymer. In another embodiment, a PS polymer block and a P4VP polymer block can be randomly copolymerized. For example, the image layer 120 can be formed by using PS-b-P4VP whose molecular weight (Mn,_{PS}) of a PS block can be about 238,100 g/mol, whose molecular weight (Mn,_{P4VP}) of a P4VP block can be about 49,500 g/mol, and whose average molecular weight (Mw/Mn) is 1.23.

In an embodiment herein, a block copolymer coating layer including PS-co-P4VP can be formed on top of the image layer 120. In another embodiment, each unit polymer block forming the PS-co-P4VP may be vertically arranged in a lamellar form on the image layer 120.

In a further embodiment, the image layer 120 may be formed of silane having an organic substituent, chlorosilane having an organic substituent, silazane having an organic substituent, a polymer having chlorosilane group at its terminal end, an organic compound having a COBr functional group, an organic compound having a thiol group, or an organic compound having a disulfide (—S—S—) bond. For example, the image layer 120 may be formed of (R₁)—SiCl₃, (R₂)₃—SiCl, (R₃)₃—SiH, (R₄)Si(OCH₂CH₃)₃, (R₅)Si(OCH₃)₃, (R₆)—SH or (R₇)—S—S—(R₈). Here, R₁, R₂, R₃, R₄, R₅, R₆, R₇, and R₈ are each an aliphatic or aromatic hydrocarbon group of substituted or non-substituted C₁ to C₂₀.

Still a further embodiment, the image layer 120 may be formed of a homopolymer or a random polymer having a terminal trichlorosilane group. For example, the image layer 120 may be formed of a homopolymer such as polystyrene having a terminal trichlorosilane group, polyhydroxystyrene having a terminal trichlorosilane group, or polymethyl metacrylate having a terminal trichlorosilane group, or a random polymer such as polyhydroxystyrene-polymethyl metacrylate having a terminal trichlorosilane group.

In an alternative embodiment, image layer 120 may be formed of a monomolecular layer formed in a self-assembly method on the surface of the etching layer 110. For example, when the image layer 120 is formed of chlorosilane, an —OH functional group exposed on the top surface of the etching layer 110 reacts with chlorosilane so as to form an Si—O—Si bond. Accordingly, a monomolecular layer is formed as a chlorosilane molecule and is self-assembled on the exposed top surface of the substrate 100. In a still alternative embodiment, the etching layer 110 can be formed of a metal layer, such as Au or the like. In a further embodiment, the image layer 120 can be formed using an organic compound having a thiol group or a silane group, or an organic compound having a disulfide (—S—S—) bond. Then, a monomolecular layer can be formed as the organic compound is self-assembled on the surface of the metal layer by having the thiol group, silane group, or a portion of the disulfide (—S—S—) bond act as an anchoring group.

In an embodiment herein, when the etching layer 110 is formed of a silicon containing material, the image layer 120 can be formed by being self-assembled on a sub-layer as reactive molecules including a reactive functional group, such as chlorosilane, a silane group containing material, a thiol group containing material, or a disulfide bond containing group, it forms a covalent bond with the reactive functional group. In another embodiment, when the etching layer 110 is formed of a metal, such as Pt, Cu, or Au, the image layer 120 can be formed by being self-assembled on the sub-layer as the metal and S-atom form a chemical bond. Accordingly, when the image layer 120 is a monomolecular layer formed in a self-assembly method on the top surface of a lower layer, damage to the image layer 120 due to a solvent or a washing solution in later processes may be prevented. Also, since the thickness of the image layer 120 is a monomeric thickness, the image layer 120 is sufficiently removed by a conventional dry etching process for manufacturing a conventional semiconductor device.

Referring to FIG. 1D, a block copolymer coating layer 130 can be formed on the image layer 120. In one embodiment, a spin process may be used to form the block copolymer coating layer 130. In an alternative embodiment, a spin coating process may be used to form the block copolymer coating layer 130.

The block copolymer coating layer 130 may include a block copolymer that is formed of at least two repeating units having different chemical structures. In one embodiment, the block copolymer coating layer 130 may include a diblock copolymer or a triblock copolymer. In another embodiment, the block copolymer coating layer 130 may include a diblock copolymer in which a first repeating unit and a second repeating unit form a covalent bond in the form of (first repeating unit)-co-(second repeating unit), or a triblock copolymer in which the first repeating unit and the second repeating unit form a covalent bond in the form of (first repeating unit)-co-(second repeating unit)-co-(first repeating unit).

In a further embodiment, the block copolymer may be a linear or branched polymer. In still a further embodiment the block copolymer has a molecular weight of up to about million g/mol of molecular weight, and in still an even further embodiment from about 3,000 up to 2,000,000 g/mol of molecular weight.

In an embodiment herein, when the block copolymer is formed of the first and second repeating units, the block copolymer may be polystyrene-polymethylmethacrylate copolymer, polybutadiene-polybutylmethacrylate copolymer, polybutadiene-polydimethylsiloxane copolymer, polybutadiene-polymethylmethacrylate copolymer, polybutadiene-polyvinylpyridine copolymer, polybutylacrylate-polymethylmethacrylate, polybutylacrylate-polyvinylpyridine, polyisoprene-polyvinylpyridine, polyisoprene-polymethylmethacrylate, polyhexylacrylate-polyvinylpyridine, polyisobutylene-polybutylmethacrylate, polyisobutylene-polymethylmethacrylate, polyisobutylene-polybutylmethacrylate, polyisobutylene-polydimethylsiloxane, polybutylmethacrylate-polybutylacrylate, polyethylethylene-polymethylmethacrylate, polystyrene-polybutylmethacrylate, polystyrene-polybutadiene, polystyrene-polyisoprene, polystyrene-polydimethylsiloxane, polystyrene-polyvinylpyridine, polyethylethylene-polyvinylpyridine, polyethylene-polyvinylpyridine, polyvinylpyridine-polymethylmethacrylate, polyethyleneoxide-polyisoprene, polyethyleneoxide-polybutadiene, polyethyleneoxide-polystyrene, polyethyleneoxide-polymethylmethacrylate, polyethyleneoxide-polydimethylsiloxane, or a polystyrene-polyethyleneoxide. In another embodiment, each block copolymer may be a diblock copolymer, in which the first and second repeating units form a covalent bond in the form of (first repeating unit)-co-(second repeating unit), or a triblock copolymer, in which the first and second repeating units form a covalent bond in the form of (first repeating unit)-co-(second repeating unit)-co-(first repeating unit). In a further embodiment, the block copolymer may be a triblock copolymer, in which the first repeating unit, the second repeating unit, and a third repeating unit form a covalent bond in the form of (first repeating unit)-co-(second repeating unit)-co-(third repeating unit). However, the examples of the block copolymer are not limited to those described above, and may include various multi-component block copolymers without departing from the spirit and scope of the present technology.

In an embodiment, the block copolymer coating layer 130 may include a diblock copolymer or a triblock copolymer formed of the first and second repeating units, a first homopolymer including the same repeating unit as the first repeating unit, and a second homopolymer including the same repeating unit as the second repeating unit. For example, a block copolymer included in the block copolymer coating layer 130 can be a polystyrene-polymemethylmethacrylate block copolymer, the block copolymer coating layer 130 may further include polystyrene as a first homopolymer and polymethylmethacrylate as a second homopolymer. The amount of the first and second homopolymers may be the same or different in the block copolymer coating layer 130. The quantities of the first and second homopolymers may each be from about 0 to 60 wt % based on the weight of the block copolymer.

If the block copolymer coating layer 130 further includes, in addition to a block copolymer, the first and second homopolymers, whose molecular weights can be from about 500 to 7,000 g/mol, the time required to form a self-assembly structure may be reduced while the block copolymer in the block copolymer coating layer 130 forms the self-assembly structure on the image layer 120 by being rearranged via phase separation in the later processes, compared to when the block copolymer coating layer 130 does not include the first and second homopolymers. Also, if the first and second homopolymers, whose molecular weight is from about 500 to 1,000,000 g/mol, are added to the block copolymer, the pitch of the self-assembly structure is increased while the block copolymer forms the self-assembly structure in the later processes, compared to when the first and second homopolymers are not added. Accordingly, by adjusting the molecular weights and addition quantities of the first and second homopolymers, a self-assembly structure having a desired pitch can be formed.

Alternatively, the block copolymer coating layer 130 may include the block copolymer, acid, and a surfactant. The acid may be an organic acid that can bond to at least some of the repeating units from among the repeating units forming the block copolymer, so that at least some of the some repeating units can accept a hydrogen bond. Also, a surfactant selectively can provide a hydrogen bond to each repeating unit forming the block copolymer depending on the temperature. The surfactant is soluble to at least some repeating units forming the block copolymer under certain temperature conditions. In one embodiment, when the self-assembly structure is aligned in a direction from the block copolymer coating layer 130, the processing temperature can be adjusted to facilitate a tuning process, wherein the width of each polymer block that is self-assembled with a predetermined repeating period is widened or narrowed. For example, the organic acid may be methanesulfonic acid (MSA), and the surfactant may be 3-n-pentadecylphenol (PDP).

In an embodiment herein, to form the block copolymer coating layer 130, a mixture including the block copolymer and an organic solvent is spin coated on the image layer 120, and then the image layer is dried in a vacuum. In another embodiment, the image layer 120 may be dried for approximately 48 hours at approximately 30° C. The organic solvent may be chloroform. The quantity of the block copolymer in the mixture used to form the block copolymer coating layer 130 may vary according to the thickness of the block copolymer coating layer 130. In one embodiment, the quantity of the block copolymer may be approximately 1 to 3 wt % in the mixture based on the total amount of block copolymer and organic solvent. In a further embodiment, when the quantity of the block copolymer is approximately 1 wt %, 2 wt %, and 3 wt %, respectively, the thickness of the block copolymer coating layer 130 is approximately 40 to 50 nm, 70 to 80 nm, and 120 to 150 nm.

When the block copolymer coating layer 130 includes the block copolymer, the acid, and the surfactant, the mixture for forming the block copolymer coating layer 130 may further include, in addition to the block copolymer and the organic solvent, an organic acid and the surfactant. When the mixture further includes the organic acid and the surfactant, the organic acid and the surfactant may each be included in the mixture in a molar ratio of approximately 1:1 to 1:1.5 with the block copolymer.

In another embodiment, the block copolymer coating layer 130 may further include a plasticizer. The plasticizer can be mixed with the block copolymer.

Referring to FIG. 1E, a mold 140 has a top surface 142 on which a predetermined pattern which may be in the form of a plurality of ridges 142A and a plurality of valleys 142B which are alternatively and repeatedly disposed. The top surface 142 of the mold 140 may be disposed to face the block copolymer coating layer 130. The mold 140 may be formed of silicon or polydimethylsiloxane (PDMS).

A predetermined pattern is formed on the top surface 142 of the mold 140 and may be the plurality of ridges 142A and the valleys 142B. In other embodiments, the predetermined pattern formed on the top surface 142 may have various shapes. In a further embodiment herein, the predetermined pattern may be a plurality of bar and space patterns, a plurality of line patterns in a linear or curved shape, a plurality of circular patterns, a plurality of oval patterns, or a plurality of polygonal patterns.

A self-assembled mono-molecular layer (SAM layer) 148 formed of an organic monomolecular layer may be formed on the top surface 142 of the mold 140. In an embodiment, during a stamping process using the mold 140, a relatively weak physical bond is formed between the mold 140 and the self-assembly structure of the block copolymer coating layer 130 compared to physical bond between the mold 140 and the SAM layer 148. Accordingly, when the mold 140 is separated from the self-assembly structure of the block copolymer coating layer 130 after the stamping process, a pattern lifting or a pattern collapse phenomenon due to a strong physical bond between the mold 140 and the self-assembly structure of the block copolymer coating layer 130 may be prevented. In another embodiment, the SAM layer 148 may be formed of hexamethyldisilazane (HMDS), aminopropyltriethoxysilane, 4-mercaptopyridine, or aminoethanethiol. Also, a predetermined area selected from the top surface 142 of the mold 140 may be surface processed so that the predetermined area has an affinity for any one of the repeating units forming the block copolymer included in the block copolymer coating layer 130.

The top surface 142 can be surface processed via a chemical method, physical method, or electric method. In one embodiment, both sidewalls of the ridges 142A can be surface processed via a piranha solution process, a thermal process, or a UV-ozone process so that both of the sidewalls have an affinity for a particular polymer block. As described above, by surface processing both of the sidewalls of the ridges 142A to have an affinity for the particular polymer block, self-assembly of the polymer blocks forming the block copolymer included in the block copolymer coating layer 130 can be readily arranged.

Alternatively, a random block copolymer layer (not shown) may be formed on the bottom surface of the valleys 142B so that the valleys 142B do not have selective affinity for any repeating units. In one embodiment, the random block copolymer layer may be formed of a repeating unit having the same structure as the repeating unit of the block copolymer included in the block copolymer coating layer 130. As described above, as the bottom surface of the valleys 142B is arranged to not have a selective affinity for any repeating units, nano-molecular sieves of the polymer blocks can readily be vertically aligned while the block copolymers included in the block copolymer coating layer 130 are rearranged via phase separation.

Referring to FIG. 1F, the predetermined pattern formed on the top surface 142 of the mold 140 can be transferred to the block copolymer coating layer 130 via a stamping process using the mold 140. In an embodiment herein, while the block copolymer coating layer 130 is filled in the valleys 142B of the mold 140, the repeating units of the block copolymer in the block copolymer coating layer 130 are rearranged via phase separation by an external stimulus 150, such as thermal or UV irradiation. In a further embodiment, the valleys 142B filled with the block copolymer coating layer 130 may be annealed at a temperature higher than the glass transition temperature (Tg) of the block copolymer. For example, the annealing process may be performed for about 24 hours in a vacuum oven that maintains a temperature of approximately 130 to 150° C. As a result, the repeating units of the block copolymer can be rearranged via phase separation and thus self-assembled so that the polymer blocks are systematically aligned on the image layer 120. In still a further embodiment, the repeating units forming the block copolymer can be aligned in a direction guided by the mold 140, and thus the polymer blocks can be self-assembled according to the pattern formed on the mold 140. In an embodiment, the polymer blocks in the block copolymer coating layer 130 can interact with a particular part of the block copolymer due to surface energy differences, and accordingly, a self-assembly structure 130A of the block copolymer can be obtained as illustrated in FIG. 1F. In FIG. 1F, the self-assembly structure 130A is formed when the block copolymer included in the block copolymer coating layer 130 is a triblock copolymer. In the self-assembly structure 130A of FIG. 1F, a first polymer block 132, a second polymer block 134, and a third polymer block 136 are sequentially vertically aligned in the valleys 142B of the mold 140. Here, the first and third polymer blocks 132 and 136 may have the same structure. Specifically, when the both sidewalls of the ridges 142A are surface processed so as to have an affinity for certain polymer blocks (for example, first and third polymer blocks 132 and 136), these certain polymer blocks may be aligned to face the both sidewalls of the ridges 142A. Also, when a random block copolymer layer is formed on the valleys 142B, the polymer blocks can readily be vertically aligned on the valleys 142B.

In FIG. 1F, the block copolymer included in the block copolymer coating layer 130 is a diblock copolymer, but is not limited thereto. Although not illustrated, when the block copolymer is a diblock copolymer, a self-assembly structure, in which the first and second polymers 132 and 134 are alternatively vertically aligned on the valleys 142B of the mold 140, may be obtained.

The first, second, and third polymer blocks 132, 134, and 136 may be self-assembled in various shaped structures. These shapes can include a sphere, cylinder, lamellar, gyroid, and hexagonal perforated cylinder (HPL). These shapes can be classified according to type, structure, molecular weight, composition ratio, and volume ratio.

The widths of the ridges 142A and valleys 142B in FIG. 1F are in a ratio of about 1:1, and the self-assembly structure 130A in a first period formed of the first, second, and third polymer blocks 132, 134, and 136 which are formed on each valley 142B. However, these are not limited thereto. For example, the self-assembly structure 130A having various pitches and periods may be formed according to shapes and width ratios of the ridges 142A and the valleys 142B. This will be described later in detail.

Referring to FIG. 1G, the mold 140 can be separated from the self-assembly structure 130A.

Referring to FIG. 1H, via a thermal process 152 on the self-assembly structure 130A at a predetermined temperature, repeatedly arranged pitches of the first, second, and third polymer blocks 132, 134, and 136, can be changed. Then, the self-assembly structure 130A is quickly cooled so as to form a tuned self-assembly structure 130B.

In an embodiment herein, the thermal process 152 can be performed on the self-assembly structure 130A at a predetermined temperature selected from a temperature range in which the surfactant included in the block copolymer coating layer 130 selectively forms a hydrogen bond with any one structure from among polymer block structures forming the first, second, and third polymer blocks 132, 134, and 136. As a result, the surfactant can selectively melt in some polymer blocks from among the first, second, and third polymer blocks 132, 134, and 136. Here, the pitch of the self-assembly structure 130A changes according to the selective melting characteristic of the surfactant in the self-assembly structure 130A. In the tuned self-assembly structure 130B of FIG. 1H, the first and third polymer blocks 132 and 136 have substantially the same structure, and the widths of the first and third polymer blocks 132 and 136 increase from a first width W1 to a second width W2 by the thermal process 152. Here, due to the selective melting characteristic of the surfactant, the width of the second polymer block 134 may decrease.

In one embodiment, when the self-assembly structure 130A is formed from the block copolymer coating layer 130 including a PS-b-P4VP block copolymer, methanesulfonic acid (MSA) as organic acid, and 3-n-pentadecylphenol (PDP) as a surfactant, the self-assembly structure 130A has a structure wherein a P4VP polymer block is combined with MSA and PS polymer blocks are each separated and vertically aligned. Here, PDP does not melt in the PS polymer block in a temperature range of about room temperature to 125° C., but selectively melts in the P4VP polymer block combined with MSA. Accordingly, the tuned self-assembly structure 130B is formed by adjusting the temperature of the self-assembly structure 130A. For example, when the self-assembly structure 130A is thermally processed in the temperature range of about room temperature to 125° C., the pitches of the PS polymer block and the P4VP polymer block change according to the selective melting characteristic of PDP, for example, to approximately 160 nm. However, at approximately 125° C. or more, PDP non-selectively melts in the PS polymer block and the P4VP polymer block. Accordingly, when the self-assembly structure 130A is thermally processed at approximately 125° C. or more, the pitches of the PS polymer block and the P4VP polymer block may be relatively small, approximately 117 nm.

In FIG. 1H, the widths of the first and third polymer blocks 132 and 136 are increased by finely tuning the self-assembly structure 130A. However, increasing of the widths is not limited to the technology depicted in FIG. 1H. In various embodiments, the width of any polymer block selected from among the first, second, and third polymer blocks 132, 134, and 136 may be changed by suitably selecting the type of block copolymer, the type of surfactant, and the temperature of the thermal process 152. As such, the tuned self-assembly structure 130B may be obtained by changing the widths and pitches of the self-assembly structure 130A. If the surfactant is not included in the block copolymer coating layer 130 such as the one formed in FIG. 1D, the forming of the tuned self-assembly structure 130B described with reference to FIG. 1H may be omitted.

Referring to FIG. 1I, a self-assembly fine pattern 130C for an etch mask, which is formed of polymer blocks remaining after removing some polymer blocks selected from among the first, second, and third polymer blocks 132, 134, and 136, is formed. In FIG. 1I, the self-assembly fine pattern 130C for an etch mask, which is formed of the first and third polymer blocks 132 and 136, is formed by removing the second polymer block 134. However, this is not limited thereto, and the self-assembly fine pattern 130C may be formed of the second polymer block 134 by removing the first and third polymer blocks 132 and 136.

In order to remove some of the polymer blocks selected from among the first, second, and third polymer blocks 132, 134, and 136, the tuned self-assembly structure 130B can be photolyzed, for example, via an ozone process, UV irradiation, or oxygen plasma exposure, and then the photolyzed portion can be stripped away using a cleaning solution. For example, when the self-assembly structure 130A or the tuned self-assembly structure 130B is a PS-PB-PS self-assembly structure formed of a PS (polystyrene) polymer block and a PB (polybutadiene) polymer block, the PB polymer block may be selectively removed via an ozone process. Alternatively, when the self-assembly structure 130A or the tuned self-assembly structure 130B is the PS-PB-PS self-assembly structure, the self-assembly fine pattern 130C formed of the PB polymer block may be formed by removing the PS polymer block after hardening the PB polymer block by exposing the self-assembly structure 130A or the tuned self-assembly structure 130B to a density hardening material, such as OsO4 or RuO4.

Referring to FIG. 1J, a fine pattern 110A can be formed by etching the image layer 120 by using the self-assembly fine pattern 130C as a etch mask, and then etching the etching layer 110 by using the self-assembly fine pattern 130C as the etch mask.

When the image layer 120 is formed of a monomolecular layer, in one embodiment, the thickness of the image layer 120 can be approximately 1 to 10 nm, and thus the image layer 120 is not readily etched. However, the image layer 120 can be readily etched under the etching conditions for the etching layer 110. Thus, while etching the image layer 120 by using the self-assembly fine pattern 130C, separate etching conditions for the image layer 120 may not be established. If the forming of the etching layer 110 is omitted, a desired fine pattern may be formed by etching the substrate 100 by using the self-assembly fine pattern 130C as an etch mask.

Referring to FIG. 1K, the self-assembly fine pattern 130C is removed, and unnecessary layers on the fine pattern 110A are removed. The pitch of the fine pattern 110A is relatively small compared to the pitch of a pattern formed by the ridges 142A and the valleys 142B on the top surface 142 of the mold 140.

In the method of forming a fine pattern according to a current embodiment of the present technology described with reference to FIGS. 1A through 1K, the width ratio of the ridge 142A and the valley 142B of the mold 140 can be about 1:1. However, such a width ratio is not limited thereto. The fine pattern may be formed by using the mold 140 including the ridges 142A and the valleys 142B in various width ratios, such as in one embodiment from about 1:4 to 4:1, in another embodiment from about 1:3 to 3:1, and in still a further embodiment from about 1:2 to 2:1.

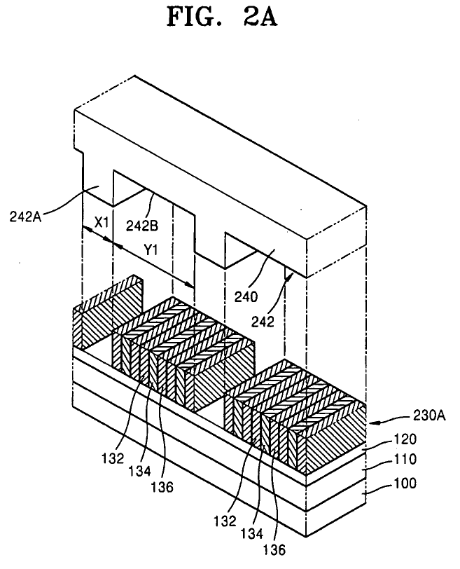

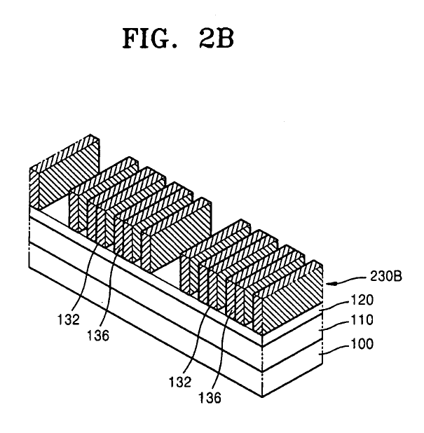

FIGS. 2A and 2B are diagrams for describing a method of forming a fine pattern according to another embodiment of the present technology.

The method according to the current embodiment is similar to the method according to the previous embodiment. However, the method according to the previous embodiment uses the mold 140 including the ridges 142A and the valleys 142B having a width ratio for purposes of illustration of about 1:1. The method according to the current embodiment uses a mold 240 including ridges 242A and valleys 242B on a top surface 242 of the mold 240, wherein a ratio of the width X1 of the ridge 242A and the width Y1 of the valley 242B for purposes of illustration is about 1:3. Like reference numerals in FIGS. 1A through 1K and FIGS. 2A and 2B denote like elements, and thus any further detailed description thereof will be omitted.

A method according to the current embodiment will now be hereinafter described in detail. First, an etching layer 110 and an image layer 120 are formed on a substrate 100 according to the same method as described with reference to FIGS. 1A through 1D. Then, a block copolymer coating layer 130 is formed on the image layer 120 (see FIG. 1D).

In an embodiment herein, a predetermined pattern can be formed on the top surface 242 of the mold 240 comprising a plurality of the ridges 242A and a plurality of the valleys 242B which are alternatively repeatedly disposed. The predetermined pattern can be transferred to a block copolymer coating layer 130. In one embodiment, a stamping process can be employed. Then, according to the same method described with reference to FIG. 1F, polymer blocks forming a block copolymer included in the block copolymer coating layer 130 can be aligned in a direction guided by the mold 240. In a further embodiment, this can be accomplished via thermal or UV irradiation. The block copolymer coating layer 130 can thereby be hardened. As a result, as illustrated in FIG. 2A, a self-assembly structure 230A can be formed, where a first polymer block 132, a second polymer block 134, and a third polymer block 136 are sequentially vertically aligned on each valley 242B of the mold 240. A stamping process can be performed using the mold 240 whose width ratio of the ridge 242A and the valley 242B can be about 1:3, and the width X1 of the ridge 242A can be equal to about the width of the ridge 142A of FIG. 1E. Polymer blocks of a first period can be formed as in FIG. 1E, and the first, second, and third polymer blocks 132, 134, and 136 can be sequentially vertically formed on one valley 142B of the mold 140. In the current embodiment, as illustrated in FIG. 2A, polymer blocks of a third period, where the first, second, and third polymer blocks 132, 134, and 136 are sequentially vertically formed on one valley 242B of the mold 240, can be formed.

Comparing FIG. 2A and FIG. 1E, a plurality of polymer blocks can be aligned in a third period on one valley 242B of the mold 240 in FIG. 2A. As such, by adjusting the width of the valley 242B, a period of polymer blocks aligned on the valley 242B may be adjusted.

Referring to FIG. 2B, the mold 240 can be separated from the self-assembly structure 230A, and then the second polymer block 134 can be selectively removed. Accordingly, a self-assembly fine pattern 230B for an etch mask including only the first and third polymer blocks 132 and 136 on the image layer 120 can be formed. However, the self-assembly fine pattern 230B is not limited thereto. For example, the self-assembly fine pattern 230B including only the second polymer block 134 may be formed by removing the first and third polymer blocks 132 and 136 from among the first, second, and third polymer blocks 132, 134, and 136.

Then, according to the same method as described with reference to FIG. 1J, the image layer 120 and the etching layer 110 may be etched by using the self-assembly fine pattern 230B as an etch mask.

Also, although not illustrated, before forming the self-assembly fine pattern 230B, a tuning process may be performed on the self-assembly structure 230A obtained in FIG. 2A by using a selective melting characteristic according to the temperature of a surfactant as described with reference to FIG. 1H.

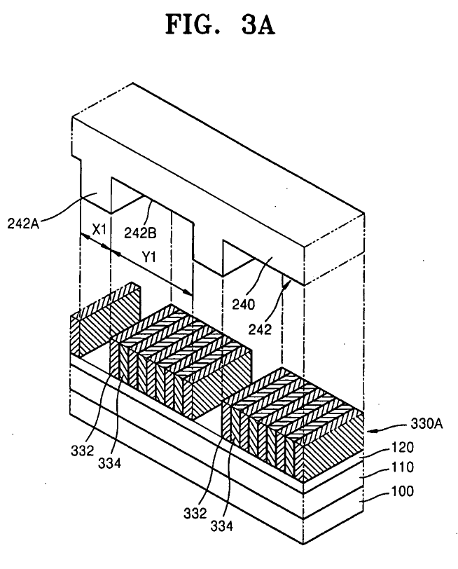

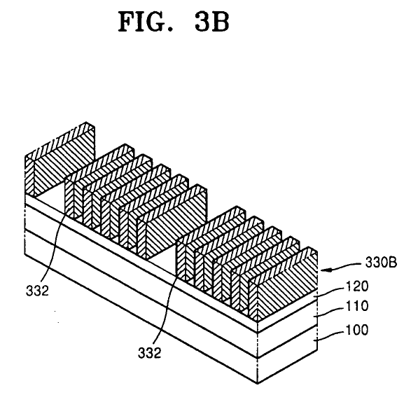

FIGS. 3A and 3B are diagrams for describing a method of forming a fine pattern according to another embodiment of the present technology.

The method according to the current embodiment is similar to the method according to the previous embodiment described with reference to FIGS. 2A and 2B. However in the current embodiment, a block copolymer included in a block copolymer coating layer 130 can be a diblock copolymer. Like reference numerals in the drawings denote like elements, and thus further detailed description thereof will be omitted.

The method according to the current embodiment will now be described in detail. First, an etching layer 110 and an image layer 120 can be formed on a substrate 100 according to the same method as described with reference to FIGS. 1A through 1D. Then, the block copolymer coating layer 130 including the diblock copolymer can be formed on the image layer 120 (refer to FIG. 1D).

Then, a predetermined pattern formed on a top surface 242 of the mold 240 can be transferred onto the block copolymer coating layer 130 via a stamping process using the mold 240. Then, polymer blocks forming the block copolymer included in the block copolymer coating layer 130 can be aligned in a direction guided by the mold. In an embodiment herein, alignment can be accomplished via thermal or UV irradiation according by the same method as described with reference to FIG. 1F, and the block copolymer coating layer 130 can be hardened. As a result, as illustrated in FIG. 3A, a self-assembly structure 330A, wherein a first polymer block 332 and a second polymer block 334 can be alternatively vertically aligned on each valley 242B of the mold 240, can be formed. FIG. 3A illustrates the self-assembly structure 330A where the first and second polymer blocks 332 and 334 can be alternatively, repeatedly, and vertically aligned on one valley 242B of the mold 240.

In FIG. 3B, a self-assembly fine pattern 330B for an etch mask formed of only the first polymer block 332 can be formed on the image layer 120 by separating the mold 240 from the self-assembly structure 330A and then selectively removing the second polymer block 334. However, the self-assembly fine pattern 330B is not limited thereto. For example, the self-assembly fine pattern 330B may be formed of only the second polymer block 334 by removing the first polymer block 332.

Then, the image layer 120 and the etching layer 110 can be etched according to the same method as described with reference to FIG. 1J by using the self-assembly fine pattern 330B as an etch mask.

Also, although not illustrated, before forming the self-assembly fine pattern 330B, a tuning process may be performed on the self-assembly structure 330A obtained in FIG. 3A by using a selective melting characteristic according to the temperature of a surfactant as described with reference to FIG. 1H.

In the present technology, in order to form a pattern having a minute pitch required in manufacturing a highly integrated semiconductor device that exceeds a resolution limitation of a photolithography process, a block copolymer coating layer can be formed on a substrate, a pattern can be transferred to the block copolymer coating layer via a stamping process using a mold, and then a self-assembly structure of a block copolymer can be formed so as to form a fine pattern of high density formed of polymer blocks. According to the method of the present technology, widths of ridges and valleys of the mold are adjusted so as to adjust a period of the polymer blocks. Also, a fine pattern disposed in a desired width and interval can be formed by selectively tuning the width of each polymer block by using a surfactant included in the block copolymer coating layer. Specifically, a spontaneous self-assembly is induced using a block copolymer in various structures, such as a triblock copolymer having A-B-C or A-B-A as a first period (A, B, and C are each a polymer block), and a diblock copolymer having A-B as a first period, by using a predetermined pattern formed on the top surface of the mold as a guide. Accordingly, by selectively removing a certain polymer block from the self-assembly structure of the block copolymer, a remarkably fine pattern can be obtained compared to the pattern formed on the mold. Also, by adjusting the type of block copolymer and the widths of the ridges and valleys of the mold, a fine pattern that is repeatedly formed in a pitch, in various embodiments reduced to about ½, about ⅓, or even more of the pitch of the pattern formed on the mold can be obtained.

According to the present technology, a molecular-sized fine structure obtained via a self-assembly phenomenon of a block copolymer can be used in processes of manufacturing a semiconductor device. Since the density of the pattern can be increased by using the self-assembly phenomenon of the block copolymer, the density of the pattern can be readily increased without adding a separate process for increasing the density of a fine pattern. Moreover, a fine pattern formed in a repeating structure having minute pitches that are difficult to realize in a conventional photolithography process can be readily formed.

According to the method of forming a fine pattern of the present technology, a molecular-sized fine structure can be formed by using a spontaneous self-assembly characteristic of a block copolymer, unlike in the case of a conventional photolithography process. Accordingly, a fine pattern repeating structure can easily be formed in a large area at low unit cost without using separate facilities.

While the present technology has been particularly shown and described with reference to exemplary embodiments thereof, it will be understood by those of ordinary skill in the art that various changes in form and details may be made therein without departing from the spirit and scope of the present technology as defined by the following claims.

What is claimed is:

1. A method of forming a fine pattern on a semiconductor device, comprising:
forming a coating layer including a block copolymer having a plurality of repeating units on a substrate;
providing a mold having a first pattern comprising a plurality of ridges and valleys;
transferring said first pattern from said mold into the coating layer;
forming a self-assembly structure comprising a plurality of polymer blocks aligned in a direction guided by the ridges and valleys of the mold thereby rearranging the repeating units of the block copolymer within the coating layer by phase separation while the coating layer is located within the valleys of the mold; and
removing a portion of the polymer blocks from among the plurality of polymer blocks and forming a self-assembly fine pattern of remaining polymer blocks.

2. The method of claim 1, wherein the forming of the coating layer comprises spin-coating a mixture including the block copolymer and an organic solvent on the substrate.

3. The method of claim 2, wherein the mixture further includes an acid and a surfactant.

4. The method of claim 3, wherein the block copolymer and the acid are mixed in a molar ratio from about 1:1 to 1:1.5.

5. The method of claim 3, wherein the block copolymer and the surfactant are mixed in a molar ratio from about 1:1 to 1:1.5.

6. The method of claim 3, wherein the block copolymer comprises polystyrene-co-poly(4-vinylpyridine) (PS-co-P4VP), the acid comprises methanesulfonic acid (MSA), and the surfactant comprises 3-n-pentadecylphenol (PDP).

7. The method of claim 1, wherein the block copolymer is formed of a multi-component block copolymer including a plurality of repeating units having different polymeric structures.

8. The method of claim 1, wherein the block copolymer is a triblock copolymer in which a first repeating unit and a second repeating unit are covalently bonded as follows: (first repeating unit)-co-(second repeating unit)-co-(first repeating unit).

9. The method of claim 1, wherein the block copolymer is a triblock copolymer in which the first repeating unit, the second repeating unit, and a third repeating unit are covalently bonded as follows: (first repeating unit)-co-(second repeating unit)-co-(third repeating unit).

10. The method of claim 1, wherein the block copolymer is a diblock copolymer in which the first repeating unit and the second repeating unit are covalently bonded as follows: (first repeating unit)-co-(second repeating unit).

11. The method of claim 1, wherein the ridges and valleys of the mold each have substantially uniform widths.

12. The method of claim 1, wherein at least a portion of the valleys have substantially larger widths than the ridges.

13. The method of claim 1, wherein during the transferring of the first pattern, a self-assembled monomolecular (SAM) layer formed of an organic monomolecular layer is produced on the surfaces of the ridges and the valleys.

14. The method of claim 13, wherein the SAM layer comprises any one of hexamethyldisilazane (HMDS), aminopropyltriethoxysilane, 4-mercaptopyridine, and aminoethanethiol.

15. The method of claim 1, further comprising, before transferring of the first pattern, surface processing a first area of the mold, so that the first area has a greater affinity for a repeating unit of the block copolymer than the other area of the mold.

16. The method of claim 15, wherein said ridges include sidewalls, and the first area comprises the sidewalls of the ridges of the mold.

17. The method of claim 15, wherein the surface processing of the first area is performed using one of a piranha solution process, a thermal process, or a UV-ozone process.

18. The method of claim 1, further comprising, before the transferring of the first pattern, surface processing a second area so that the second area does not have a selective affinity for the repeating units of the block copolymer.

19. The method of claim 18, wherein said valleys comprise bottom surfaces, and the second area comprises the bottom surfaces.

20. The method of claim 18, wherein said surface processing of said second area comprises forming a random block copolymer layer.

21. The method of claim 20, wherein the random block copolymer layer includes the same repeating units as the block copolymer in the coating layer.

22. The method of claim 1, wherein the mold is formed of one of silicon or polydimethylsiloxane (PDMS).

23. The method of claim 1, wherein during the forming of the self-assembly structure, heat is applied to the coating layer so as to rearrange the repeating units of the block copolymer in the coating layer via phase separation.

24. The method of claim 1, wherein in the forming of the self-assembly structure, UV is irradiated onto the coating layer so as to rearrange the repeating units of the block copolymer in the coating layer via phase separation.

25. The method of claim 1, wherein the plurality of polymer blocks in the self-assembly structure are self-assembled as at least one of a sphere, cylinder, lamellar, gyroid, or hexagonal perforated cylinder (HPL) structure.

26. The method of claim 1, wherein the coating layer comprises the block copolymer, acid for combining with the block copolymer so that the block copolymer accepts a hydrogen bond, and a surfactant for providing hydrogen bonding to the block copolymer.

27. The method of claim 26, wherein the acid comprises methanesulfonic acid (MSA), and the surfactant comprises 3-n-pentadecylphenol (PDP).

28. The method of claim 1, further comprising, before removing said portion of the polymer blocks, changing pitch when the plurality of repeating units of the polymer blocks are rearranged.

29. The method of claim 1, further comprising, before removing some of the polymer blocks, forming a tuned self-assembly structure by increasing the widths of at least a portion of the polymer blocks.

30. The method of claim 29, wherein the polymer blocks include a surfactant, and a selective melting characteristic based on the temperature of the surfactant is used to form the tuned self-assembly structure.

31. The method of claim 29, further comprising adjusting the temperature of the self-assembly structure above ambient temperature to form the tuned-self-assembly structure.

32. The method of claim 1, wherein in forming the self-assembly fine pattern, the plurality of polymer blocks are processed using one of an ozone, UV irradiation, or oxygen plasma process to remove at least a portion of the polymer blocks.

33. The method of claim 1, wherein the forming of the self-assembly fine pattern comprises selectively hardening at least a portion of the remaining polymer blocks.

34. The method of claim 33, wherein selectively hardening at least a portion of the remaining polymer blocks comprises exposure to one of OSO₄ or RuO.

35. The method of claim 1, further comprising, before the forming of the coating layer, forming an image layer on the substrate, wherein the coating layer is formed on the image layer.

36. The method of claim 35, wherein the image layer is formed of a random block copolymer.

37. The method of claim 35, wherein the image layer is formed of a monomolecular layer self-assembled by a chemical bond on the surface of the substrate.

38. The method of claim 35, further comprising, before the forming of the image layer, forming an etching layer on the substrate, wherein the image layer is formed on the etching layer.

39. The method of claim 38, wherein the etching layer is formed of one of an oxide layer, a nitride layer, a nitride oxide layer, a doped polysilicon layer, or a metal layer.

40. The method of claim 38, further comprising, before forming the image layer, surface processing the top surface of the etching layer so that Si—OH is exposed on the top surface of the etching layer.

41. The method of claim 38, further comprising:
exposing the etching layer by etching an exposed portion of the image layer, using the self-assembly fine pattern as an etch mask; and
etching the etching layer using the self-assembly fine pattern as an etch mask.
